(19) United States
(12) Patent Application Publication
(10) Pub. No.: US 2005/0241581 A1
(43) Pub. Date: Nov. 3, 2005

(54) Chemical vapor deposition apparatuses and deposition methods

(76) Inventors: Craig M. Carpenter, Boise, ID (US); Ross S. Dando, Nampa, ID (US); Philip H. Campbell, Meridian, ID (US); Allen P. Mardian, Boise, ID (US); Jeff N. Fuss, Meridian, ID (US); Randy W. Mercil, Boise, ID (US)

Correspondence Address: WELLS ST. JOHN P.S., 601 W. FIRST AVENUE, SUITE 1300, SPOKANE, WA, 99201, US

(21) Appl. No.: 11/175,523

(22) Filed: Jul. 5, 2005

Related U.S. Application Data
(62) Division of application No. 09/810,387, filed on Mar. 15, 2001.

(51) Int. Cl. C23C 16/00

(52) U.S. Cl. 118/715; 427/248.1

(57) ABSTRACT

A chemical vapor deposition (CVD) apparatus includes a deposition chamber defined partly by a chamber wall. The chamber wall has an innermost surface inside the chamber and an outermost surface outside the chamber. The apparatus further includes a valve body having a seat between the innermost and outermost surfaces of the chamber wall. The chamber wall can be a lid and the valve can include a portion of the lid as at least a part of the seat. The valve body can include at least a part of a valve housing between the innermost and outermost surfaces of the chamber wall. Such a valve body can even include a portion of the chamber wall as at least part of the valve housing. The deposition apparatus can further include at least a part of a process chemical inlet to the valve body between the innermost and outermost surfaces of the chamber wall. In one example, the chamber wall can form at least a part of the chemical inlet. A deposition method includes temporarily isolating a process chemical supply line from a deposition chamber at a chamber wall of the deposition chamber. While isolated at the chamber wall, the supply line can be filled to a first pressure with chemical through a supply valve upstream from the chamber wall. The chemical can be released from the supply line into the deposition chamber at the chamber wall. The supply line can be again temporarily isolated from the deposition chamber at the chamber wall.

### TECHNICAL FIELD

The present invention pertains to chemical vapor deposition apparatuses, such as atomic layer deposition apparatuses, and deposition methods.

### BACKGROUND OF THE INVENTION

Chemical vapor deposition (CVD) methods, such as atomic layer deposition (ALD) methods, are often used in semiconductor processing and other industrial applications to form thin layers of materials. One consideration in selecting a deposition method is the process time to form a desired layer. Along with an increasing need to reduce processing costs, a related desire exists to reduce process time. Speaking generally of ALD, a substrate is exposed to a first precursor material that is chemisorbed onto the substrate. The first precursor material is purged from the deposition chamber and a second precursor material chemisorbed onto the first precursor material on the substrate. Theoretically, the chemisorption of each precursor material is self limiting and the deposited material is formed one monolayer (one atom thick) at a time. In practice, the ideal theoretical deposition is often not achieved or may be intentionally altered.

One potential cause for a deviation from ideal conditions is the simultaneous presence of the first precursor and the second precursor somewhere in a deposition apparatus other than on the substrate. For example, mixture of the first precursor and the second precursor in a supply line may cause reaction of the precursors and deposition in the supply line. Similarly, failure to completely purge one of the precursors from a deposition chamber may cause unwanted deposition on chamber components when the other precursor is introduced. Unwanted mixing of precursors can be a leading cause of particulate formation and product contamination in ALD.

Accordingly, the need to improve product quality and minimize downtime for cleaning provides a motivation for careful purging practices. Unfortunately, careful purging increases process time and accompanying process costs.

### BRIEF DESCRIPTION OF THE DRAWINGS

Preferred embodiments of the invention are described below with reference to the following accompanying drawings.

FIG. 1 shows a diagram of a deposition chamber and a related process chemical delivery system according to an aspect of the invention.

FIG. 2 shows a cross-sectional diagram of a fragment of the deposition chamber in FIG. 1 according to one aspect of the invention.

FIG. 3 shows a cross-sectional diagram of a fragment of the deposition chamber in FIG. 1 modified according to an alternative aspect of the invention.

### SUMMARY OF THE INVENTION

According to one aspect of the invention, a chemical vapor deposition (CVD) apparatus includes a deposition chamber defined partly by a chamber wall. The chamber wall has an innermost surface inside the chamber and an outermost surface outside the chamber. The apparatus further includes a valve body having a seat between the innermost and outermost surfaces of the chamber wall. As an example, the CVD apparatus can be an atomic layer deposition apparatus. Also, the chamber wall can be a lid. Further, the valve can include a portion of the chamber wall as at least a part of the seat. The valve body can include at least a part of a valve housing between the innermost and outermost surfaces of the chamber wall. Such a valve body can even include a portion of the chamber wall as at least part of the valve housing. The deposition apparatus can further include at least a part of a process chemical inlet to the valve body between the innermost and outermost surfaces of the chamber wall. In one example, the chamber wall can form at least a part of the chemical inlet.

In another aspect of the invention, a CVD apparatus includes a deposition chamber having a lid and a process chemical opening completely through the lid. An isolation mechanism can be proximate the chemical opening, the lid being integral to the isolation mechanism. The isolation mechanism can selectively isolate the deposition chamber from receiving material through the chemical opening. The isolation mechanism can include a valve. The lid can include at least a part of a seat of the valve, at least a part of a housing of the valve, and/or at least a part of a process chemical inlet to the valve.

As another aspect of the invention, a CVD apparatus can include a deposition chamber having a lid and a valve body including a portion of the lid as a part of the valve body. The valve body can selectively shut off flow of a process chemical into the chamber, adjust the flow rate of the chemical into the chamber, or both.

According to a further aspect of the invention, a CVD apparatus can include a deposition chamber having a lid, the lid having an inner surface inside the chamber, an outer surface outside the chamber, and an opening defined by side walls extending between the inner and outer surfaces. A valve body of the apparatus can include a housing and a seat. At least a part of the housing can include at least a part of the outer surface of the lid, at least a part of the opening side walls of the lid, or both. At least a part of the seat can include at least a part of the inner surface of the lid, at least a part of the opening side walls of the lid, or both.

A still further aspect of the invention provides a deposition method that temporarily isolates a process chemical supply line from a deposition chamber at a chamber wall of the deposition chamber. While isolated at the chamber wall, the supply line can be filled to a first pressure with chemical through a supply valve upstream from the chamber wall. The chemical can be released from the supply line into the deposition chamber at the chamber wall. The supply line can be again temporarily isolated from the deposition chamber at the chamber wall. As an example, the method can further include closing the supply valve after filling the supply line with chemical and before the releasing the chemical into the deposition chamber.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

It is a disadvantage of current atomic layer deposition (ALD) chambers that control valves or shut off valves for gas or liquid precursors, reactants, carriers, purges, and other process chemicals are distant from a deposition chamber. After exiting a final process valve, materials may travel a substantial distance, for example about 25 cm (10 inches), before entering a deposition chamber. The supply line between the closest valve to a deposition chamber and the deposition chamber is typically purged of a first precursor prior to injecting a second precursor in ALD. Accordingly, decreasing the distance between a valve and the chamber can decrease purge time. One possible advantage of some aspects of the invention described herein is that the distance between the closest valve to a deposition chamber and the deposition chamber can be reduced. Such distance may even be eliminated, as in the case where a valve seat opens directly into the deposition chamber. Moving the final point of isolation in a supply line closer to a deposition chamber reduces purge time and also reduces the time lag in delivery of a process chemical to the deposition chamber. The cycle times of ALD can be an important consideration in optimizing ALD.

According to one aspect of the invention, a chemical vapor deposition (CVD) apparatus includes a deposition chamber and a process chemical opening completely through a chamber wall. The chamber wall can be a chamber lid, chamber body, or any other structure that encloses process chemicals in a portion of the chamber designated for deposition. As discussed above, the various aspects of the invention can be particularly advantageous in performing ALD. However, the concepts of the invention can be extended to non-ALD forms of CVD and may also be advantageous in such processing. For example, reducing the distance between a deposition chamber and the final point of isolation in a supply line can reduce unwanted mixing of precursors in a supply line during a non-ALD type of CVD. When injecting two precursors through two supply lines, a first precursor injected through a first supply line may potentially migrate into a second supply line containing a second precursor, causing deposition within the second supply line.

The CVD apparatus can further include an isolation mechanism proximate the chemical opening, the chamber wall being integral to the isolation mechanism. The isolation mechanism can selectively isolate the deposition chamber from receiving material through the chemical opening. The point where isolation occurs can be within the chemical opening in the chamber wall or elsewhere along the delivery path of chemical to the chamber. However, the chamber wall is preferably integral to the isolation mechanism such that the isolation mechanism would be incomplete, nonfunctional, or otherwise not able to isolate chemical delivery from the chamber absent the chamber wall. The opening is described broadly as a chemical opening since it is conceivable according to the concepts of the invention that any gas or liquid precursors, reactants, carriers, purges, or other process chemicals can be received through the chemical opening into the deposition chamber.

One example of an isolation mechanism is a valve. Commonly, a valve has a valve body including a seat, a plug complementary to the seat to perform an isolation and/or flow control function, and a stem linked to the plug. All elements can be encased in a housing. The valve can additionally include a valve actuator linked to the stem, and possibly the housing, that operates the plug to open and close the valve. The chamber wall can comprise at least a part of a seat of the valve. Also, the chamber wall can include at least a part of a housing of the valve. Further, the chamber wall can include at least a part of a process chemical inlet to the valve.

A variety of actuators are known to those skilled in the art and may later be developed that are suitable to the invention, including electrical, pneumatic, mechanical, etc. actuators. Similarly, a variety of valve bodies are known to those skilled in the art and may later be developed that can be suitable to the invention, including plug, diaphragm, gate, globe, metering, etc. valves. Within individual types of valve bodies, a further variety of plug configurations and seat configurations can be suitable. The plug-and-seat geometry can be significant factor in determining the flow characteristics. Also, some seats might be more easily incorporated into a chamber wall, such as a lid, than others. Once the unique aspects of the invention described herein are understood, the invention concepts and examples might be practiced by adapting any of the valve types indicated as well as others not particularly described herein. Further, isolation mechanisms may exist that are not commonly regarded as valves, but nevertheless provide a structure that achieves the advantages of the present invention.

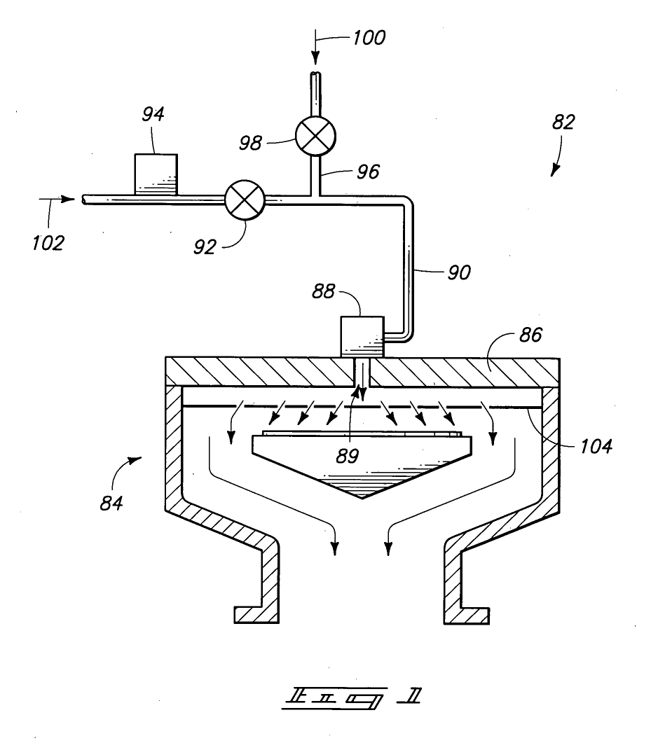

Turning to FIG. 1, a deposition apparatus 82 is shown including a deposition chamber 84 having a lid 86. Lid 86 can merely be a top wall of chamber 84 that is otherwise not a separate or removable component of chamber 84. Preferably, lid 86 is a separate and removable component of chamber 84. Lid 86 can be attached to form chamber 84 by clamping, bolting, or any other acceptable method for a CVD apparatus. Lid 86 could also be welded, making it nonremovable. For selected aspects of the invention described below, it may be advantageous for lid 86 to be removable for maintenance on valves.

FIG. 1 shows an isolation mechanism 88 positioned over a process chemical opening 89 extending completely through lid 86. Although not shown, a plurality of process chemical openings can extend through lid 86 and a plurality of isolation mechanisms can be provided for the openings. A supply line 90 linked to isolation mechanism 88 delivers a process chemical 102 to chamber 84. A flow controller 94 operates on a supply valve 92 to adjust the delivery rate of process chemical 102. When providing a plurality of chemical openings and isolation mechanisms, delivery of a different process chemical can be controlled through each opening. Accordingly, purging of supply lines can be reduced and cycle time improved. Notably, supply valve 92 can be considered optional and flow controller 94 can instead operate isolation mechanism 88. Accordingly, isolation mechanism 88 might be a control valve. Further, a separate flow controller could be provided for supply valve 92 as well as isolation mechanism 88. A flow controller, as known to those skilled in the art, can be distinguished from mechanisms that merely open and close a valve, etc. A mass flow controller is preferred in the aspects of the present invention.

In a typical conventional apparatus, isolation mechanism 88 would not be present and supply line 90 would deliver process chemical 102 directly to chemical opening 89. Accordingly, purging of supply line 90 between supply valve 92 and lid 86 would be common. Similarly, a time lag might occur after opening of supply valve 92 before process chemical 102 would be delivered to chamber 84. An optional purge line 96, purge valve 98, and purge gas 100 are also shown in FIG. 1 in a position that can accomplish purging of at least a portion of supply line 90.

In another aspect of the invention, a CVD apparatus includes a deposition chamber defined partly by a chamber wall, the chamber wall having an innermost surface inside the chamber and an outermost surface outside the chamber. The apparatus further includes a valve body having a seat between the innermost and outermost surfaces of the chamber wall. Preferably, the valve body includes a portion of the chamber wall as at least a part of the seat. However, it is conceivable that a seat can be between the innermost and outermost surfaces of the chamber wall without the chamber wall being at least a part of the seat. For example, a complete valve could be mounted to the chamber wall through an opening in the chamber wall. Similarly, the valve body can include at least a part of a valve housing between the innermost and outermost surfaces of the chamber wall. Again, preferably the valve body includes a portion of the chamber wall as at least a part of the valve housing. Further, the CVD apparatus can include at least a part of a process chemical inlet to the valve body between the innermost and outermost surfaces of the chamber wall. A preferred chamber wall can form at least a part of the precursor inlet.

As a further aspect of the invention, a CVD apparatus includes a deposition chamber having a lid and a valve body including a portion of the lid as part of the valve body. The valve body can selectively shut off flow of a process chemical into the chamber, adjust the flow rate of the chemical into the chamber, or both. That is, in the present invention a valve incorporated into a deposition chamber lid can be a shut-off valve, a control valve, or can be a control valve that also acts as a shut-off valve. Accordingly, at a 50% open position as indicated by a stem position, the valve body might provide a flow rate of no more than about ≈50% of a maximum flow rate through the valve body.

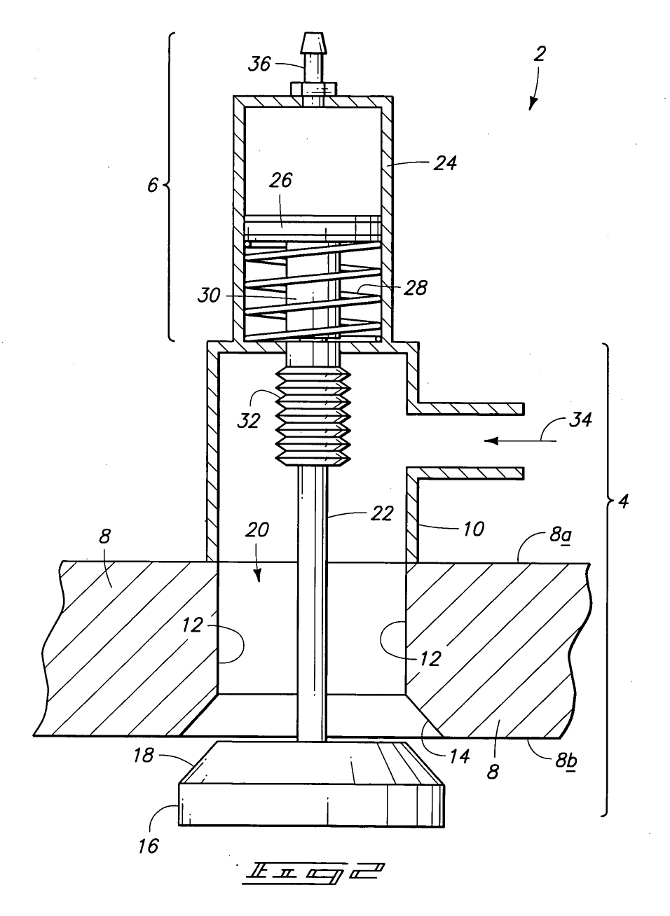

A variety of possibilities exist for a valve body to include a portion of the chamber lid. As a first example, a portion of the chamber lid can include at least a part of a valve housing. In FIG. 2, a valve 2 is shown having a combined valve body and a chamber lid identified as a group by reference numeral 4 and a valve actuator identified as a group by reference numeral 6. As is apparent from FIG. 2, the part of a housing 10 comprised by a lid 8 between an outermost surface 8a and an innermost surface 8b is defined by a cylindrical opening 20 having side walls 12 in lid 8. Valve body 4 further includes a stem 22 coincident with a central axis of cylindrical opening 20 and positioned at least partially within cylindrical opening 20.

As a second example, a portion of the lid can include at least a part of a valve seat. In FIG. 2, the entirety of a seat 14, as a plug-type seat, is between innermost surface 8b inside the chamber and outermost surface 8a outside the chamber. Further, the part of seat 14 comprised by lid 8 is defined by a beveled lid surface around cylindrical opening 20 through lid 8. Valve body 4 further includes a plug 16 complementary to the beveled lid surface of seat 14. Accordingly, a plug seal 18 can be pressed against seat 14 to close valve body 4.

FIG. 2 shows one example of a pneumatic actuator. A housing 24 encloses a piston 26. A spring 28 biases piston 26 upward and a connecting rod 30 linking stem 22 to piston 26. A bellows 32 isolates any process chemical delivered through a process chemical inlet 34 from passing into valve actuator 6. By applying a pressure signal to a signal inlet 36, piston 26 compresses downward against spring 28 to move stem 22 downward and separate plug seal 18 from seat 14, opening valve body 4. Accordingly, if a pressure signal is lost, valve body 4 will automatically close.

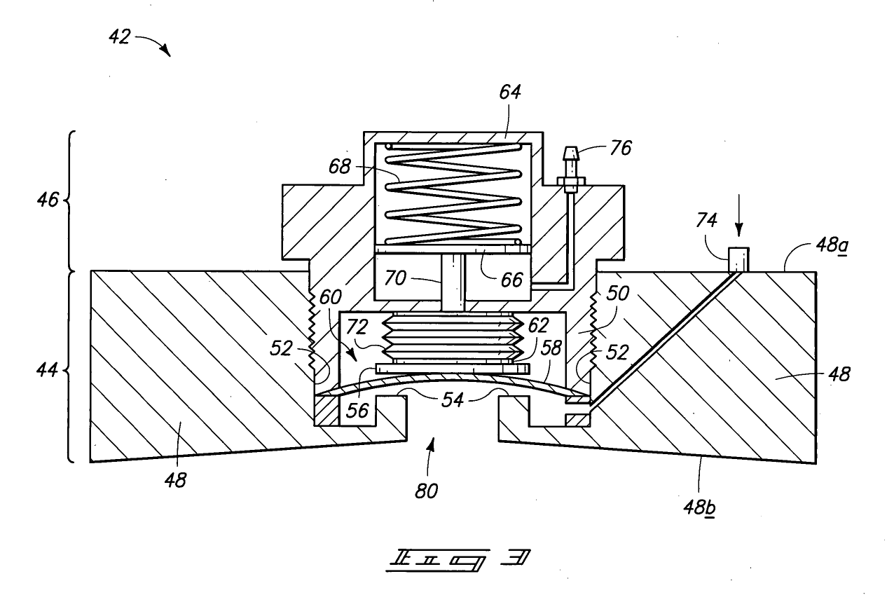

Turning to FIG. 3, a valve 42 is shown having a combined valve body and a chamber lid identified as a group by reference numeral 44. As is apparent from FIG. 3, the part of a housing 50 comprised by a lid 48 between an outermost surface 48a and an innermost surface 48b is defined by a cylindrical opening 60 having side walls 52 in lid 48. Valve body 44 further includes a stem 62 coincident with a central axis of cylindrical opening 60 and positioned at least partially within cylindrical opening 60. Further, the entirety of a seat 54, as a diaphragm-type seat, is between innermost surface 48b inside the chamber and outermost surface 48a outside the chamber. The part of seat 54 comprised by lid 48 is defined by an annular platform around a cylindrical opening 80 through lid 48. Valve body 44 further includes a plug 56 and a diaphragm 58 between plug 56 and seat 54.

As a third example of a valve body including a portion of the chamber lid, a portion of the lid can include at least a part of a process chemical inlet in the valve body. In FIG. 3, process chemical inlet 74 passes through lid 48 to side walls 52 opening into cylindrical opening 60. Accordingly, chemical inlet 74 is in what can be considered part of housing 50 though part of lid 48 as well as in further removed portions of lid 48.

FIG. 3 also shows another example of a pneumatic actuator. A housing 64 encloses a piston 66, a spring 68 biasing piston 66, and a connecting rod 70 linking stem 62 to piston 66. A bellows 72 isolates any process chemical delivered through chemical inlet 74 from passing into valve actuator 46 in the event that diaphragm 58 ruptures. By reducing a pressure signal to a signal inlet 76, spring 68 compresses downward against piston 66 to move stem 62 downward and compress diaphragm 58 against seat 54, closing valve body 4. Accordingly, if a pressure signal is lost, valve body 4 will automatically close.

In a still further aspect of the invention, a CVD apparatus includes a deposition chamber having a lid and an opening defined by side walls extending between an inner surface of the lid inside the chamber and an outer surface of the lid outside the chamber. The apparatus can further include a valve body having a housing and a seat. At least a part of the housing can include at least a part of the outer surface of the lid, at least a part of the opening side walls of the lid, or both. At least a part of the seat can include at least a part of the inner surface of the lid, at least a part of the opening side walls of the lid, or both.

According to an aspect of the invention, a deposition method includes providing a process chemical supply line to a chamber wall of a deposition chamber. The supply line can be temporarily isolated from the deposition chamber at the wall. While isolated at the wall, the supply line can be filled with chemical through a supply valve upstream from the wall. The supply line can be filled to a first pressure. Chemical can be released from the supply line into the deposition chamber at the wall. The supply line can again be temporarily isolated from the deposition chamber at the wall. In keeping with indications above, such a deposition method can be a CVD method, and may be particularly suited as an ALD method.

Given the short cycle times in ALD where a process chemical is successively delivered to a deposition chamber, purged from the deposition chamber, and again delivered, an ability to pressurize chemical in advance for direct delivery at a chamber wall can be advantageous. For example, the supply line can be re-pressurized during purging. Accordingly, the method can include closing the supply valve after filling the supply line with chemical and before releasing chemical into the deposition chamber. Further, the method can include, while releasing chemical into the chamber, maintaining chemical in the supply line between the supply valve and the wall at about a second pressure. The first and second pressures can be about the same or can be different depending upon desired process conditions.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1-29. (canceled)

30. A chemical vapor deposition method comprising:
providing a process chemical supply line to a chamber wall partly defining a deposition chamber;
temporarily isolating the supply line from the deposition chamber at the chamber wall;
while isolated at the chamber wall, filling the supply line with chemical through a supply valve upstream from the chamber wall, the supply line being filled to a first pressure;
releasing chemical from the supply line into the deposition chamber at the chamber wall; and
again temporarily isolating the supply line from the deposition chamber at the chamber wall.

31. The method of claim 30 wherein the chamber wall comprises a lid.

32. The method of claim 30 further comprising, while releasing chemical into the deposition chamber, maintaining chemical in the supply line between the supply valve and the chamber wall at about a second pressure.

33. The method of claim 31 wherein the first and second pressures are about the same.

34. The method of claim 30 further comprising closing the supply valve after the filling the supply line with chemical and before the releasing the chemical into the deposition chamber.

35. The method of claim 30 further comprising purging chemical from the deposition chamber after again temporarily isolating the supply line from the deposition chamber.

36. The method of claim 30 wherein the chemical vapor deposition method comprises atomic layer deposition.
